(19) United States
(12) Patent Application Publication
(10) Pub. No.: US 2024/0407101 A1
(43) Pub. Date: Dec. 5, 2024

(54) LAYERED CERAMIC ELECTRONIC COMPONENT MOUNTING STRUCTURE

(71) Applicant: Murata Manufacturing Co., Ltd., Nagaokakyo-shi (JP)

(72) Inventor: Toshihiro HARADA, Nagaokakyo-shi (JP)

(21) Appl. No.: 18/800,548

(22) Filed: Aug. 12, 2024

Related U.S. Application Data
(63) Continuation of application No. PCT/JP2023/019377, filed on May 24, 2023.

(30) Foreign Application Priority Data
Sep. 2, 2022 (JP) 2022-139916

(51) Int. Cl. H05K 1/18; H01G 2/06; H01G 4/232; H01G 4/30; H05K 1/11

(52) U.S. Cl. CPC H05K 1/181; H01G 2/06; H01G 4/2325; H01G 4/30; H05K 1/111; H05K 2201/10015; H05K 2201/10022; H05K 2201/1003

(57) ABSTRACT

A layered ceramic electronic component mounting structure includes a layered ceramic electronic component mounted on a circuit board. The layered ceramic electronic component includes a layered body including an inner conductor layer and dielectric layers, and first and second outer electrodes located on only two principal surfaces or on only one principal surface of the layered body. The circuit board includes first and second land electrodes. An inside end of the first outer electrode is closer to the second outer electrode and the second land electrode than an inside end of the first land electrode, and an inside end of the second outer electrode is closer to the first outer electrode and the first land electrode than an inside end of the second land electrode.

### CROSS REFERENCE TO RELATED APPLICATIONS

This application claims the benefit of priority to Japanese Patent Application No. 2022-139916 filed on Sep. 2, 2022 and is a Continuation Application of PCT Application No. PCT/JP2023/019377 filed on May 24, 2023. The entire contents of each application are hereby incorporated herein by reference.

### BACKGROUND OF THE INVENTION

### 1. Field of the Invention

The present invention relates to mounting structures for multilayer ceramic electronic components.

### 2. Description of the Related Art

Multilayer ceramic electronic components using ceramics are known as surface mount type electronic components. For example, Japanese Unexamined Patent Application, Publication No. 2016-76582 discloses a multilayer ceramic capacitor as such a multilayer ceramic electronic component. This type of multilayer ceramic capacitor includes a multilayer body formed by stacking a plurality of dielectric layers including ceramic material and a plurality of internal electrode layers (inner conductive layers), and two external electrodes respectively located on the two end surfaces of the multilayer body.

In the mounting structure for mounting such multilayer ceramic electronic components on a circuit board, the external electrodes of the multilayer ceramic electronic components are connected to the land electrodes of the circuit board. With this type of mounting structure, a paste solder fillet is formed on the external electrodes on the end surfaces of the multilayer ceramic electronic components during the mounting process of the multilayer ceramic electronic components, thereby stabilizing the mounting posture of the multilayer ceramic electronic components.

### SUMMARY OF THE INVENTION

There is a demand for further downsizing such multilayer ceramic electronic components. There is also a demand for higher-density mounting in the mounting structures for such multilayer ceramic electronic components. Conceivable approaches for high-density mounting may include reducing the occupied area of the paste solder fillet formed on the external electrodes on the end surfaces of the multilayer ceramic electronic components. In this regard, instead of providing the external electrodes on the end surfaces of the multilayer ceramic electronic components, the external electrodes may be provided on the mounting surfaces of the multilayer ceramic electronic components.

However, according to the insights of the inventors, in the case of multilayer ceramic electronic components without external electrodes on the end surfaces, paste solder fillets are not formed on the end surfaces of the multilayer ceramic electronic components during the mounting process of the multilayer ceramic electronic components, resulting in an unstable mounting posture such as floating or tilting of the multilayer ceramic electronic components. Such decrease in stability of the mounting posture becomes more pronounced with the downsizing of the multilayer ceramic electronic components.

Example embodiments of the present invention provide mounting structures for multilayer ceramic electronic components, each of which decrease or prevent a reduction in the stability of a mounting posture.

A mounting structure for a multilayer ceramic electronic component according to an example embodiment of the present invention includes a multilayer ceramic electronic component mounted on a circuit board, the multilayer ceramic electronic component including a multilayer body including a plurality of dielectric layers including ceramic material and a plurality of inner conductive layers stacked on each other, the multilayer body including two main surfaces on opposite sides in a thickness direction, two lateral surfaces on opposite sides in a width direction intersecting with the thickness direction, and two end surfaces on opposite sides in a length direction intersecting with both the thickness direction and the width direction, and first and second external electrodes spaced apart in the length direction, provided on only the two main surfaces of the multilayer body or only one of the two main surfaces of the multilayer body, in which the circuit board includes a first land electrode and a second land electrode that are spaced apart in the length direction, and are respectively connected to the first external electrode and the second external electrode of the multilayer ceramic electronic component, an inner edge of the first external electrode on a second external electrode side in the length direction is located closer to the second external electrode side and a second land electrode side, than an inner edge of the first land electrode on the second land electrode side in the length direction, and an inner edge of the second external electrode on a first external electrode side in the length direction is located closer to the first external electrode side and a first land electrode side, than an inner edge of the second land electrode on the first land electrode side in the length direction.

Example embodiments of the present invention decrease or prevent a reduction in the stability of a mounting posture, in the mounting structures for multilayer ceramic electronic components.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view illustrating a multilayer ceramic capacitor (multilayer ceramic electronic component) according to an example embodiment of the present invention.

FIG. 2 is a cross-sectional view along the line II-II (WT cross-section) of the multilayer ceramic capacitor (multilayer ceramic electronic component) illustrated in FIG. 1.

FIG. 3A is a cross-sectional view along the line IIIA-IIIA (LT cross-section) of the multilayer ceramic capacitor (multilayer ceramic electronic component) illustrated in FIG. 2.

FIG. 3B is a cross-sectional view along the line IIIB-IIIB (LT cross-section) of the multilayer ceramic capacitor (multilayer ceramic electronic component) illustrated in FIG. 2.

FIG. 4 is a perspective view illustrating the mounting structure for a multilayer ceramic capacitor (multilayer ceramic electronic component) according to an example embodiment of the present invention.

FIG. 5 is a side view illustrating the mounting structure for a multilayer ceramic capacitor (multilayer ceramic electronic component) according to an example embodiment of the present invention.

FIG. 6 is a side view illustrating the mounting structure for a multilayer ceramic capacitor (multilayer ceramic electronic component) according to an example embodiment of the present invention.

FIG. 7 is a side view illustrating the mounting structure for the multilayer ceramic capacitor (multilayer ceramic electronic component) related to a comparative example.

FIG. 8 is a side view illustrating the mounting structure for the multilayer ceramic capacitor (multilayer ceramic electronic component) related to another comparative example.

### DETAILED DESCRIPTION OF THE EXAMPLE EMBODIMENTS

Hereinafter, example embodiments of the present invention will be described with reference to the accompanying drawings. The same or corresponding portions in each drawing are denoted by the same reference numerals.

### Multilayer Ceramic Capacitor: Multilayer Ceramic Electronic Component

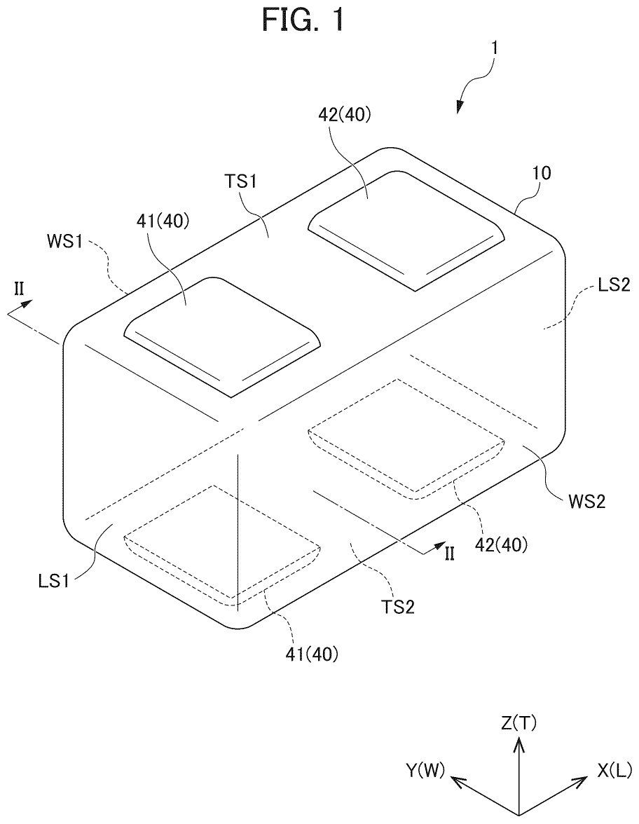

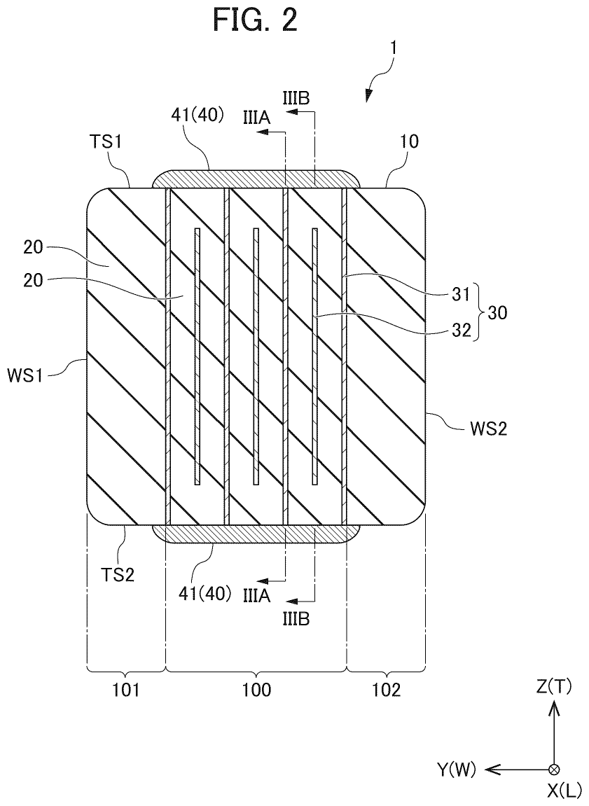

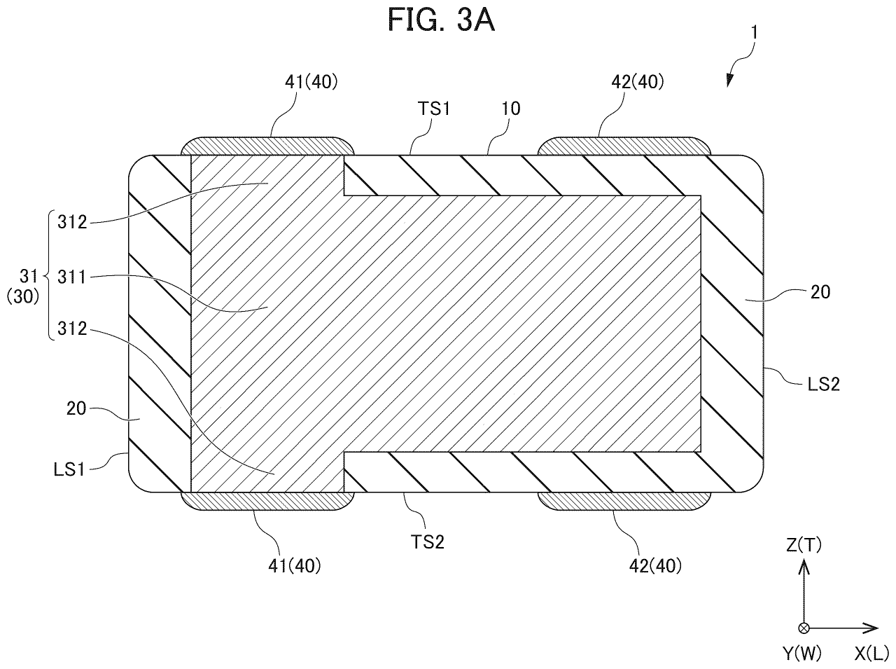

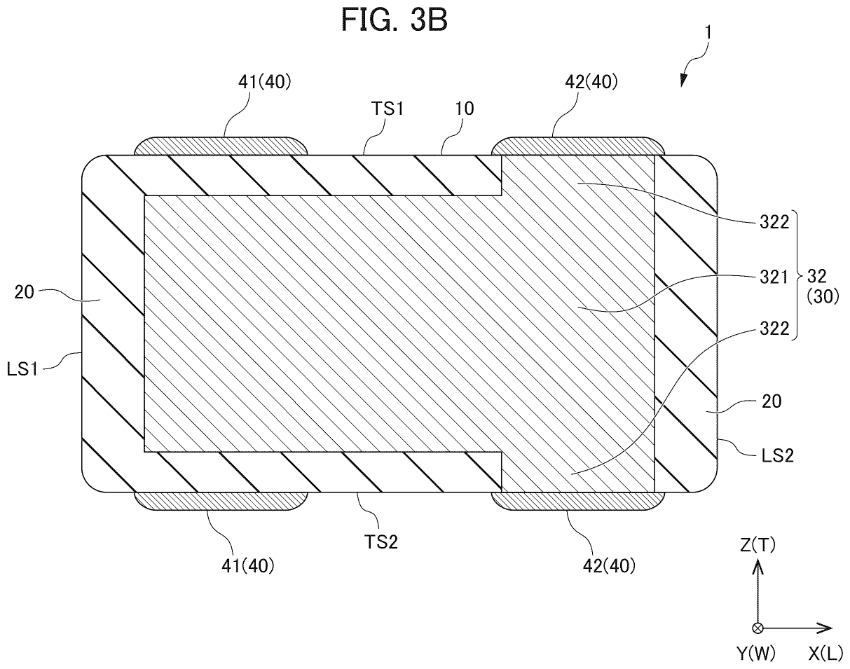

FIG. 1 is a perspective view illustrating a multilayer ceramic capacitor (multilayer ceramic electronic component) according to the present example embodiment, and FIG. 2 is a cross-sectional view along the line II-II (WT cross-section) of the multilayer ceramic capacitor (multilayer ceramic electronic component) illustrated in FIG. 1. FIG. 3A is a cross-sectional view along the line IIIA-IIIA (LT cross-section) of the multilayer ceramic capacitor (multilayer ceramic electronic component) illustrated in FIG. 2, and FIG. 3B is a cross-sectional view along the line IIIB-IIIB (LT cross-section) of the multilayer ceramic capacitor (multilayer ceramic electronic component) illustrated in FIG. 2. The multilayer ceramic capacitor (multilayer ceramic electronic component) 1 illustrated in FIGS. 1 to 3B includes a multilayer body 10 and two sets of external electrodes 40. Each set of external electrodes 40 includes a first external electrode 41 and a second external electrode 42.

FIGS. 1 to 3B and the drawings described later illustrate the XYZ Cartesian coordinate system. The X-direction is the length direction L of the multilayer ceramic capacitor 1 and the multilayer body 10, the Y-direction is the width direction W of the multilayer ceramic capacitor 1 and the multilayer body 10, and the Z-direction is the thickness direction T of the multilayer ceramic capacitor 1 and the multilayer body 10. Thus, the cross-section illustrated in FIG. 2 is also referred to as the WT cross-section, and the cross-section illustrated in FIGS. 3A and 3B is also referred to as the LT cross-section.

The length direction L, the width direction W, and the thickness direction T are not necessarily orthogonal to each other and may intersect.

The multilayer body 10 has a substantially rectangular parallelepiped shape and includes a first main surface TS1 and a second main surface TS2 on opposite sides in the thickness direction T, a first lateral surface WS1 and a second lateral surface WS2 on opposite sides in the width direction W, and a first end surface LS1 and a second end surface LS2 on opposite sides in the length direction L.

The corners and edge lines of the multilayer body 10 are preferably rounded. The corners are the portions where three surfaces of the multilayer body 10 intersect, and the edge lines are the portions where two surfaces of the multilayer body 10 intersect.

As illustrated in FIGS. 2, 3A, and 3B, the multilayer body 10 includes a plurality of dielectric layers 20 and a plurality of internal electrode layers 30 stacked in the width direction W. The multilayer body 10 includes an inner layer portion 100 as well as a first outer layer portion 101 and a second outer layer portion 102 sandwiching the inner layer portion 100 in the width direction W, i.e., the lamination direction.

The inner layer portion 100 includes part of the plurality of dielectric layers 20 and the plurality of internal electrode layers (inner conductive layers) 30. In the inner layer portion 100, the plurality of internal electrode layers 30 are provided facing each other across the dielectric layers 20. The inner layer portion 100 is the portion that generates capacitance and functions substantially as a capacitor (effective region).

The first outer layer portion 101 is provided on the first lateral surface WS1 side of the multilayer body 10, and the second outer layer portion 102 is provided on the second lateral surface WS2 side of the multilayer body 10. More specifically, among the plurality of internal electrode layers 30, the first outer layer portion 101 is provided between the first lateral surface WS1 and an internal electrode layer 30 closest to the first lateral surface WS1, while the second outer layer portion 102 is provided between the second lateral surface WS2 and another internal electrode layer 30 closest to the second lateral surface WS2. The first outer layer portion 101 and the second outer layer portion 102 do not include the internal electrode layers 30, and respectively include portions of the plurality of dielectric layers 20 that are not part of the inner layer portion 100. The first outer layer portion 101 and the second outer layer portion 102 function as the protective layers for the inner layer portion 100.

The dielectric layers 20 can be made of dielectric ceramics that primarily include materials such as BaTiO₃, CaTio₃, SrTiO₃, or CaZro₃. Additionally, the dielectric layers 20 may include materials such as Mn, Fe, Cr, Co, or Ni compounds as secondary components. More specifically, the dielectric layers 20 include a plurality of dielectric grains. The dielectric grains are barium titanate-based ceramics, such as perovskite-type compounds including Ba and Ti. These dielectric grains may include at least one of La, Ce, Pr, Nd, Sm, Eu, Gd, Tb, Dy, Ho, Er, Tm, Yb, Lu, or Y as secondary components.

The thickness of the dielectric layers 20 is not particularly limited but may, for example, be between about 0.40 μm and about 1.00 μm inclusive. The number of the dielectric layers 20 is not particularly limited but may, for example, be between 10 layers and 1000 layers inclusive. The number of the dielectric layers 20 is the total number of the dielectric layers in the inner layer portion and the dielectric layers in the outer layer portion.

As illustrated in FIGS. 2, 3A, and 3B, the plurality of internal electrode layers 30 include a plurality of first internal electrode layers 31 and a plurality of second internal electrode layers 32. The plurality of first internal electrode layers 31 and the plurality of second internal electrode layers 32 are alternately arranged in the width direction W of the multilayer body 10, i.e., the lamination direction.

The first internal electrode layer 31 includes a counter electrode portion 311 and an extension electrode portion 312, and the second internal electrode layer 32 includes a counter electrode portion 321 and an extension electrode portion 322.

The counter electrode portion 311 and the counter electrode portion 321 face each other across the dielectric layers 20 in the width direction T of the multilayer body 10, i.e., the lamination direction. The shapes of the counter electrode portion 311 and the counter electrode portion 321 are not particularly limited, and may be substantially rectangular, for example. The counter electrode portion 311 and the counter electrode portion 321 form the portion (effective region) that generates capacitance and functions substantially as a capacitor.

The extension electrode portion 312 extends from a portion of the first end surface LS1 side of the multilayer body 10 in the counter electrode portion 311 toward the first main surface TS1 of the multilayer body 10, and is exposed at the first main surface TS1. The extension electrode portion 312 extends from a portion of the first end surface LS1 side of the multilayer body 10 in the counter electrode portion 311 toward the second main surface TS2 of the multilayer body 10, and is exposed at the second main surface TS2. The extension electrode portion 322 extends from a portion of the second end surface LS2 side of the multilayer body 10 in the counter electrode portion 321 toward the first main surface TS1 of the multilayer body 10, and is exposed at the first main surface TS1. The extension electrode portion 322 extends from a portion of the second end surface LS2 side of the multilayer body 10 in the counter electrode portion 321 toward the second main surface TS2, and is exposed at the second main surface TS2 of the multilayer body 10. The shapes of the extension electrode portion 312 and the extension electrode portion 322 are not particularly limited, and may be substantially rectangular, for example.

As a result, the first internal electrode layer 31 is connected to the first external electrode 41 provided on the first main surface TS1 and the second main surface TS2 of the multilayer body 10, and is spaced apart from the second external electrode 42 provided on the first main surface TS1 and the second main surface TS2 of the multilayer body 10. The second internal electrode layer 32 is connected to the second external electrode 42 provided on the first main surface TS1 and the second main surface TS2 of the multilayer body 10, and is spaced apart from the first external electrode 41 provided on the first main surface TS1 and the second main surface TS2 of the multilayer body 10.

The first internal electrode layer 31 and the second internal electrode layer 32 include metal Ni as a principal component. The first internal electrode layer 31 and the second internal electrode layer 32 may also include at least one selected from metals such as Cu, Ag, Pd, Au, or alloys such as an Ag—Pd alloy including at least one of these metals, either as a principal component or a non-principal component. Furthermore, the first internal electrode layer 31 and the second internal electrode layer 32 may also include particles of a dielectric material from the same compositional family as the ceramic included in the dielectric layers 20, as a non-principal component. In this specification, a principal component metal is defined as the metal component with the highest weight percentage.

The thickness of the first internal electrode layer 31 and the second internal electrode layer 32 is not particularly limited but may be, for example, between about 0.20 μm and about 1.00 μm inclusive. The number of the first internal electrode layers 31 and the second internal electrode layers 32 is also not particularly limited but may be, for example, between 10 layers and 1000 layers inclusive.

The dimensions of the multilayer body 10 are not particularly limited, but, for example, the length in the length direction L may be between about 0.20 mm and about 1.00 mm inclusive, the width in the width direction W may be between about 0.10 mm and about 0.50 mm inclusive, and the thickness in the thickness direction T may be between about 0.10 mm and about 0.50 mm inclusive. The dimensions of the multilayer ceramic capacitor 1, including the external electrodes 40 to be described later, are not particularly limited, but, for example, the length in the length direction L may be between about 0.20 mm and about 1.00 mm inclusive, the width in the width direction W may be between about 0.10 mm and about 0.50 mm inclusive, and the thickness in the thickness direction T may be between about 0.10 mm and about 0.50 mm inclusive.

A method of measuring the thickness of the dielectric layers 20 and the internal electrode layers 30 may involve using a scanning electron microscope to observe a WT cross-section near the central area in the length direction of the multilayer body, which has been exposed by polishing. The values obtained may be averages of measurements from a plurality of points in the length direction, or averages of measurements from a plurality of points in the lamination direction.

Similarly, a method of measuring the thickness of the multilayer body 10 or the multilayer ceramic capacitor 1 may involve using a scanning electron microscope to observe a WT cross-section near the central area in the length direction of the multilayer body, which has been exposed by polishing, or an LT cross-section near the central area in the width direction of the multilayer body or the multilayer ceramic capacitor, which has been exposed by polishing. The values obtained may be averages of measurements from a plurality of points in the length direction or the width direction. Similarly, a method of measuring the length of the multilayer body 10 or the multilayer ceramic capacitor 1 may involve using a scanning electron microscope to observe an LT cross-section near the central area in the width direction of the polished multilayer body or the multilayer ceramic capacitor, which has been exposed by polishing. The values obtained may be averages of measurements from a plurality of points in the thickness direction. Similarly, a method of measuring the width of the multilayer body 10 or the multilayer ceramic capacitor 1 may involve using a scanning electron microscope to observe a WT cross-section near the central area in the length direction of the polished multilayer body or the multilayer ceramic capacitor, which has been exposed by polishing. The values obtained may be averages of measurements from a plurality of points in the thickness direction.

Each of the two sets of external electrodes 40 includes a first external electrode 41 and a second external electrode 42.

The first external electrode 41 is provided on the second main surface TS2 of the multilayer body 10, specifically on a portion of the first end surface LS1 side of the second main surface TS2, and is connected to the first internal electrode layer 31. The first external electrode 41 is provided on the first main surface TS1 of the multilayer body 10, specifically on a portion of the first end surface LS1 side of the first main surface TS1, and is connected to the first internal electrode layer 31. The first external electrode 41 is not provided on the first end surface LS1 or the two lateral surfaces WS1 and WS2.

The second external electrode 42 is provided on the second main surface TS2 of the multilayer body 10, specifically on a portion of the second end surface LS2 side of the second main surface TS2, and is connected to the second internal electrode layer 32. The second external electrode 42 is also provided on the first main surface TS1 of the multilayer body 10, specifically on a portion of the second end surface LS2 side of the first main surface TS1, and is connected to the second internal electrode layer 32. The second external electrode 42 is not provided on the second end surface LS2 or the two lateral surfaces WS1 and WS2.

In the present example embodiment, two sets of external electrodes 40 are provided on the first main surface TS1 and the second main surface TS2 of the multilayer body 10, for example. However, only one set of external electrodes 40 may be formed on only one (mounting surface) of the first main surface TS1 or the second main surface TS2 of the multilayer body 10. In this example, the extension electrodes 312 and 322 are not provided on the main surface side where the one set of external electrodes 40 is not provided. In surface mount type electronic components, it is often the case that there is no distinction between the top and bottom surfaces. Therefore, two sets of external electrodes 40 are preferably provided on each of the first main surface TS1 and the second main surface TS2 of the multilayer body 10.

Each of the first external electrode 41 and the second external electrode 42 may include a base electrode layer and a plated layer. The first external electrode 41 and the second external electrode 42 may be solely composed of the plated layer.

The base electrode layer may be a fired layer including metal and glass. The glass component may include at least one of B, Si, Ba, Mg, Al, or Li. For example, borosilicate glass can be used. The metal may include Cu as the principal component. The metal may include at least one selected from metals such as Ni, Ag, Pd, or Au, or alloys such as an Ag—Pd alloy, as a principal component or non-principal component.

The fired layer is formed by applying an electrically conductive paste including metal and glass to the multilayer body by dipping, followed by firing. This layer may be fired after or simultaneously with firing the internal electrode layers. The fired layer may include a plurality of layers.

Alternatively, the base electrode layer may be a resin layer including electrically conductive particles and a thermosetting resin. The resin layer may be provided on top of the fired layer or directly on the multilayer body without a fired layer.

The resin layer is a layer formed by applying an electrically conductive paste including electrically conductive particles and thermosetting resin to the multilayer body using a coating method followed by firing. This layer may be fired after or simultaneously with firing the internal electrode layers. The resin layer may include a plurality of layers.

The thickness of each layer of the base electrode layer, whether a fired layer or a resin layer, is not particularly limited and may be between about 1 μm and about 10 μm inclusive, for example.

Alternatively, the base electrode layer may be formed by a thin film deposition method such as sputtering or evaporation, and may include a thin film layer of metal particles deposited to a thickness of about 1 μm or less, for example.

The plated layer covers at least a portion of the base electrode layer. The plated layer may include at least one selected from metals such as Cu, Ni, Ag, Pd, Au, or alloys such as an Ag—Pd alloy.

The plated layer may be formed of a plurality of layers. A two-layer structure including Ni plating and Sn plating is preferable. The Ni plated layer can prevent the base electrode layer from being eroded by solder during the mounting of ceramic electronic components, and the Sn plated layer can improve the wettability of the solder during the mounting of ceramic electronic components, facilitating easier mounting.

The thickness of each plated layer is not particularly limited and may be between about 1 μm and about 10 μm inclusive, for example.

### Manufacturing Method

Next, a non-limiting example of a manufacturing method for the previously described multilayer ceramic capacitor 1 is described. First, dielectric sheets for the dielectric layers 20 and an electrically conductive paste for the internal electrode layers 30 are prepared. The dielectric sheets and the electrically conductive paste include binders and solvents. Well-known materials can be used for the binders and solvents.

Next, for example, the electrically conductive paste is printed in predetermined patterns on the dielectric sheets, thereby forming internal electrode patterns on the dielectric sheets. Methods such as screen printing or gravure printing can be used to form the internal electrode patterns.

Then, a predetermined number of dielectric sheets for the second outer layer portion 102, which do not include the internal electrode patterns printed thereon, are stacked. On top of these, dielectric sheets for the inner layer portion 100, which include the internal electrode patterns printed, are sequentially stacked. Then, a predetermined number of dielectric sheets for the first outer layer portion 101, which do not include the internal electrode patterns printed, are stacked on top. This process creates a multilayer sheet.

Next, the multilayer sheet is pressed in the lamination direction by using, for example, a hydrostatic press to create a multilayer block. Then, the multilayer block is cut to a desired size to produce multilayer chips. In this case, the corners and the edge lines of the multilayer chips are rounded by processes such as barrel polishing. Then, the multilayer chips are fired to create the multilayer body 10. The firing temperature should preferably be between about 900° C. and about 1400° C. inclusive, for example, depending on the materials of the dielectric and the internal electrodes.

Next, an electrically conductive paste as an electrode material for the base electrode layers is applied using a coating method to the second main surface TS2 and the first main surface TS1 of the multilayer body 10. Afterwards, these electrically conductive pastes are fired to form the base electrode layer, which is a fired layer. The firing temperature should preferably be between about 600° C. and about 900° C. inclusive, for example.

The base electrode layer may also be formed as a thin film layer by thin film deposition methods such as sputtering or evaporation.

In the described process, the base electrode layers are formed and fired after the multilayer chips have been fired, meaning that the multilayer body and external electrodes are fired separately. However, the base electrode layers may be formed and fired before firing the multilayer chips, thus allowing for the simultaneous firing of the multilayer body and external electrodes.

Subsequently, a plated layer is formed on the surface of the base electrode layer to create the first external electrode 41 and the second external electrode 42. Through these steps, the previously described multilayer ceramic capacitor 1 is obtained.

### Mounting Structure

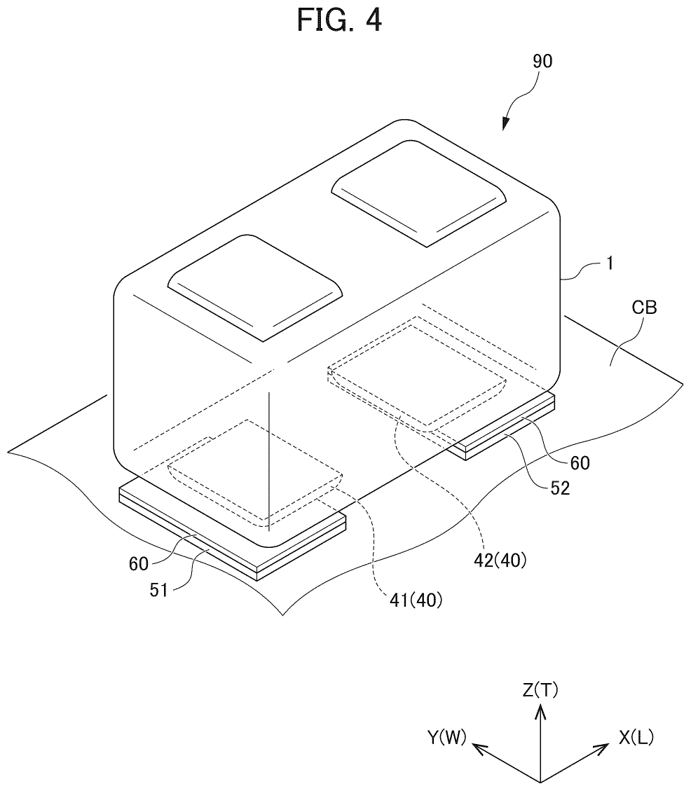

Next, the mounting structure for the multilayer ceramic capacitor 1 on the circuit board will be described. FIG. 4 is a perspective view illustrating the mounting structure for the multilayer ceramic capacitor (multilayer ceramic electronic component) according to the present example embodiment. As illustrated in FIG. 4, a mounting structure 90 includes a circuit board CB and the multilayer ceramic capacitor 1.

The circuit board CB includes a first land electrode 51 and a second land electrode 52 spaced apart in the length direction L. As described earlier, the multilayer ceramic capacitor 1 includes the first external electrode 41 and the second external electrode 42, which are spaced apart in the length direction L, at least on the second main surface TS2 (mounting surface). The first external electrode 41 of the multilayer ceramic capacitor 1 is connected to the first land electrode 51 of the circuit board CB via the paste solder 60, and the second external electrode 42 of the multilayer ceramic capacitor 1 is connected to the second land electrode 52 of the circuit board CB via the paste solder 60.

The outer edge of the first external electrode 41 on the side opposite to the second external electrode 42 in the length direction L is located closer to the second external electrode 42 side and the second land electrode 52 side, than the outer edge of the first land electrode 51 on the side opposite to the second land electrode 52 in the length direction L. The outer edge of the second external electrode 42 on the side opposite to the first external electrode 41 in the length direction L is located closer to the first external electrode 41 side and the first land electrode 51 side, than the outer edge of the second land electrode 52 on the side opposite to the first land electrode 51 in the length direction L.

The inner edge of the first external electrode 41 on the second external electrode 42 side in the length direction L is located closer to the second external electrode 42 side and the second land electrode 52 side, than the inner edge of the first land electrode 51 on the second land electrode 52 side in the length direction L. The inner edge of the second external electrode 42 on the first external electrode 41 side in the length direction L is located closer to the first external electrode 41 side and the first land electrode 51 side, than the inner edge of the second land electrode 52 on the first land electrode 51 side in the length direction L.

The distance between the inner edge of the first external electrode 41 and the inner edge of the second external electrode 42 is preferably shorter than the distance between the inner edge of the first land electrode 51 and the inner edge of the second land electrode 52.

The dimension of the first external electrode 41 and the second external electrode 42 in the length direction L is preferably at least about 74% of the dimension of the first land electrode 51 and the second land electrode 52 in the length direction L, for example.

The dimension of the first external electrode 41 and the second external electrode 42 in the width direction W may be between about 0.12 mm and about 0.21 mm inclusive, for example.

Here, as a surface mount type multilayer ceramic electronic component, the shape including external electrodes on end surfaces is well known. In such multilayer ceramic electronic components, during the mounting process of mounting the multilayer ceramic electronic components on the circuit board, a paste solder fillet is formed on the external electrodes on the end surfaces of the multilayer ceramic electronic component, thereby stabilizing the mounting posture (mountability) of the multilayer ceramic electronic components.

There is a demand for further downsizing such multilayer ceramic electronic components. There is also a demand for higher-density mounting for the mounting structures for such multilayer ceramic electronic components. From the perspective of high-density mounting, a possible approach is to reduce the occupied area of the paste solder fillets formed on the external electrodes on the end surfaces of the multilayer ceramic electronic components. In this regard, instead of providing the external electrodes on the end surfaces of the multilayer ceramic electronic components, a conceivable approach is to provide the external electrodes on the mounting surfaces of the multilayer ceramic electronic components.

However, according to the insights of the inventors, in the case of multilayer ceramic electronic components without external electrodes on the end surfaces, paste solder fillets are not formed on the end surfaces of the multilayer ceramic electronic components during the mounting process of the multilayer ceramic electronic components, resulting in an unstable mounting posture such as floating or tilting of the multilayer ceramic electronic components. Such a decrease in stability of the mounting posture becomes more pronounced with the downsizing of the multilayer ceramic electronic components.

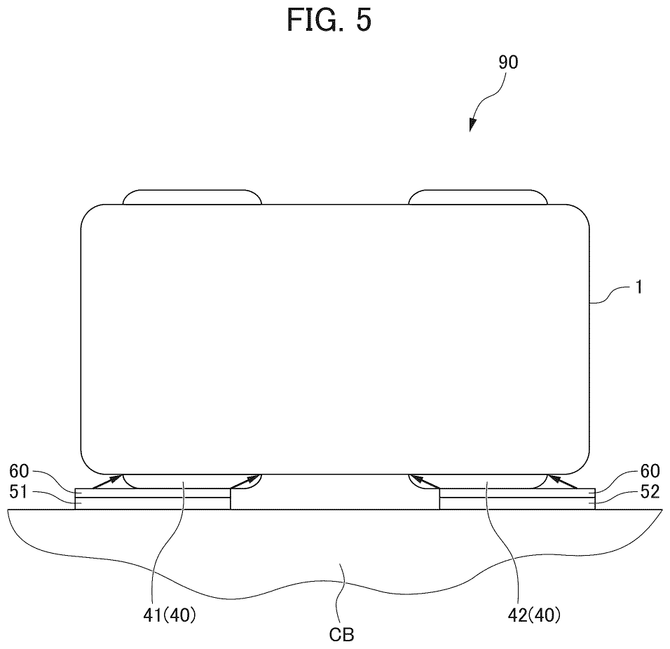

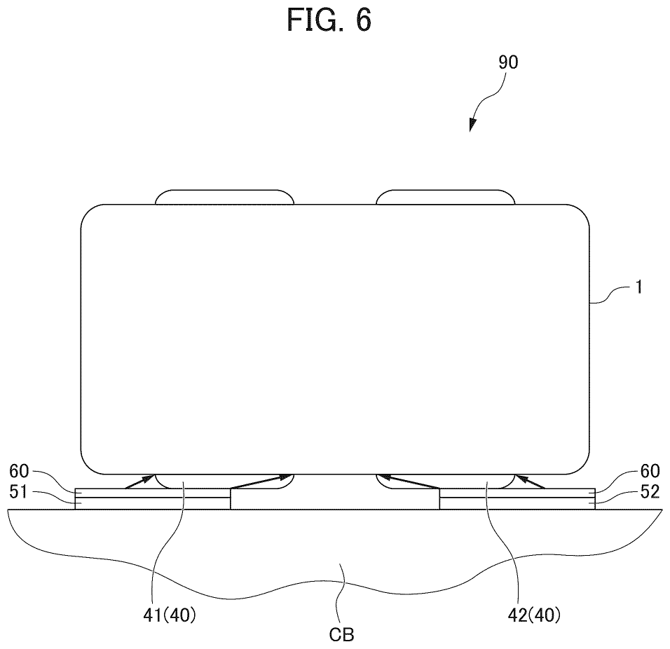

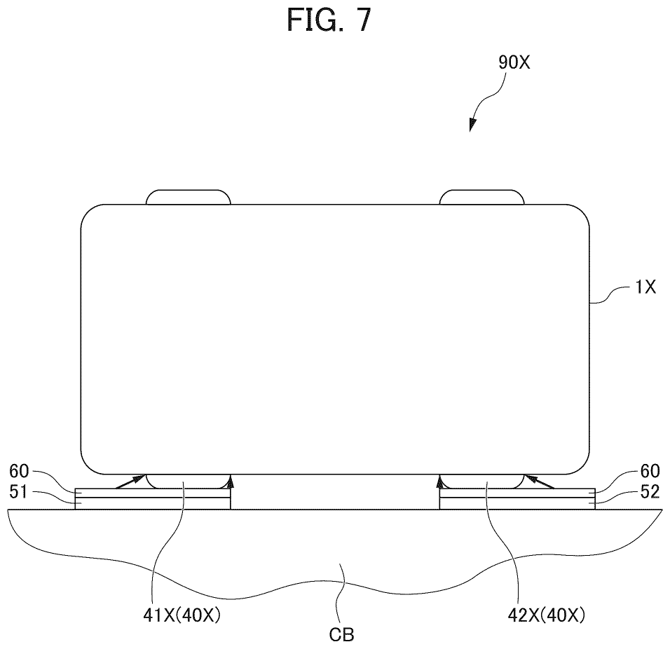

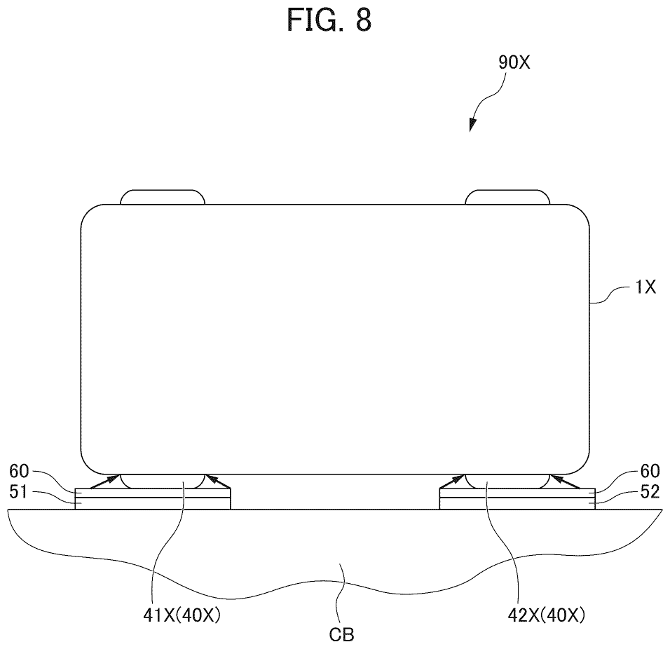

According to the experimental results of the inventors, the following insights have been obtained. FIGS. 5 and 6 illustrate side views of the mounting structure for a multilayer ceramic capacitor (multilayer ceramic electronic component) according to an example embodiment of the present invention, and FIGS. 7 and 8 illustrate side views of a mounting structure for a multilayer ceramic capacitor (multilayer ceramic electronic component) related to a comparative example.

As compared to the mounting structure 90 of the example embodiment illustrated in FIG. 5, the mounting structure 90 of the example embodiment illustrated in FIG. 6 mainly differs in the aspects described below.

The distance between the inner edge of the first external electrode 41 and the inner edge of the second external electrode 42 is shorter.

The inner edge of the first external electrode 41 is located even closer to the second external electrode 42 side and the second land electrode 52 side, than the inner edge of the first land electrode 51.

The inner edge of the second external electrode 42 is located even closer to the first external electrode 41 side and the first land electrode 51 side, than the inner edge of the second land electrode 52.

As compared to the mounting structure 90 of the example embodiment illustrated in FIG. 5, the mounting structure 90X of comparative example illustrated in FIG. 7 mainly differs in the aspects described below.

The dimension of each of the first external electrode 41X and the second external electrode 42X of the multilayer ceramic capacitor 1X is smaller. In other words, the dimension of each of the first external electrode 41X and the second external electrode 42X in the length direction L is less than about 74% of the dimension of each of the first land electrode 51 and the second land electrode 52 in the length direction L.

The inner edge of the first external electrode 41X of the multilayer ceramic capacitor 1X is located approximately at the same position as the inner edge of the first land electrode 51 in the length direction L.

The inner edge of the second external electrode 42X of the multilayer ceramic capacitor 1X is located approximately at the same position as the inner edge of the second land electrode 52 in the length direction L.

As compared to the mounting structure 90 of the example embodiment illustrated in FIG. 5, the mounting structure 90X of the comparative example illustrated in FIG. 8 mainly differs in the aspects described below.

The dimension of each of the first external electrode 41X and the second external electrode 42X of the multilayer ceramic capacitor 1X is smaller. In other words, the dimension of each of the first external electrode 41X and the second external electrode 42X in the length direction L is less than about 74% of the dimension of each of the first land electrode 51 and the second land electrode 52 in the length direction L.

The distance between the inner edge of the first external electrode 41X and the inner edge of the second external electrode 42X of the multilayer ceramic capacitor 1X is longer.

The inner edge of the first external electrode 41X of the multilayer ceramic capacitor 1X is located closer to the side opposite to the second external electrode 42X side and the second land electrode 52 side, than the inner edge of the first land electrode 51.

The inner edge of the second external electrode 42X of the multilayer ceramic capacitor 1X is located closer to the side opposite to the first external electrode 41X side and the first land electrode 51 side, than the inner edge of the second land electrode 52.

The following aspects are illustrated in FIGS. 5 to 8.

The outer edge of the first external electrode 41 (41X) is located closer to the second external electrode 42 (42X) side and the second land electrode 52 side, than the outer edge of the first land electrode 51.

The outer edge of the second external electrode 42 (42X) is located closer to the first external electrode 41 (41X) side and the first land electrode 51 side, than the outer edge of the second land electrode 52.

In this case, during the mounting process of the multilayer ceramic capacitor 1 (1X), it is considered that the force exerted from the paste solder 60 on the outer edges of the external electrodes 41, 42 (41X, 42X) will pull inward along the length direction L (see the arrows in FIGS. 5 to 8).

On the other hand, the following aspects are illustrated in FIG. 8.

The inner edge of the first external electrode 41X is located closer to the side opposite to the second external electrode 42X side and the second land electrode 52 side, than the inner edge of the first land electrode 51.

The inner edge of the second external electrode 42X is located closer to the side opposite to the first external electrode 41X side and the first land electrode 51 side than the inner edge of the second land electrode 52.

In this case, during the mounting process of the multilayer ceramic capacitor 1X, it is considered that the force exerted from the paste solder 60 on the inner edges of the external electrodes 41X, 42X will pull outward along the length direction L (see the arrows in FIG. 8). Thus, when the force exerted on the outer edges of external electrodes 41X, 42X and the force exerted on the inner edges of external electrodes 41X, 42X are oriented in the opposing directions along the length direction L, it is considered that the multilayer ceramic capacitor 1X will float and tilt.

The following aspect are illustrated in FIG. 7.

The inner edge of the first external electrode 41X is located approximately at the same position as the inner edge of the first land electrode 51 in the length direction L.

The inner edge of the second external electrode 42X is located approximately at the same position as the inner edge of the second land electrode 52 in the length direction L.

In this case, during the mounting process of the multilayer ceramic capacitor 1X it is considered that the force exerted from the paste solder 60 on the inner edges of the external electrodes 41X, 42X will push upward (see arrows in FIG. 7). Thus, when the direction of the force exerted on the outer edges of the inner edges of the external electrodes 41X, 42X differs from the direction of the force exerted on the inner edges of the inner edges of the external electrodes 41X, 42X along the length direction L, it is considered that the multilayer ceramic capacitor 1X will float and tilt.

On the other hand, the following aspects are illustrated in FIGS. 5 and 8.

The inner edge of the first external electrode 41 is located closer to the second external electrode 42 side and the second land electrode 52 side, than the inner edge of the first land electrode 51.

The inner edge of the second external electrode 42 is located closer to the first external electrode 41 side and the first land electrode 51 side, than the inner edge of the second land electrode 52.

In this case, during the mounting process of the multilayer ceramic capacitor 1, it is considered that the force exerted from the paste solder 60 on the inner edges of the external electrodes 41, 42 will pull inward along the length direction L (see the arrows in FIGS. 5 and 6). Thus, when the force exerted on the outer edges of the external electrodes 41, 42 and the force exerted on the inner edges of the outer edge of the external electrodes 41, 42 align in the same direction along the length direction L, is considered that the floating and tilting of the multilayer ceramic capacitor 1 can be reduced or prevented.

As described above, the following features are achieved according to the mounting structure 90 of the multilayer ceramic capacitor (multilayer ceramic electronic component) 1 of the present example embodiment.

The inner edge of the first external electrode 41 on the second external electrode 42 side in the length direction L is located closer to the second external electrode 42 side and the second land electrode 52 side, than the inner edge of the first land electrode 51 on the second land electrode 52 side in the length direction L.

The inner edge of the second external electrode 42 on the first external electrode 41 side is located closer to the first external electrode 41 side and the first land electrode 51 side, than the inner edge of the second land electrode 52 on the first land electrode 51 side. This feature prevents the multilayer ceramic capacitor 1 from floating and tilting during the mounting process of the multilayer ceramic capacitor 1, and decreases or prevents a reduction in stability of the mounting posture of the multilayer ceramic capacitor 1.

In the present example embodiment of the mounting structure 90 for the multilayer ceramic capacitor (multilayer ceramic electronic component) 1, the distance between the inner edge of the first external electrode 41 and the inner edge of the second external electrode 42 is preferably shorter than the distance between the inner edge of the first land electrode 51 and the inner edge of the second land electrode 52. This facilitates achieving the positional relationship between the inner edge of the first external electrode 41 and the inner edge of the first land electrode 51, and the positional relationship between the inner edge of the second external electrode 42 and the inner edge of the second land electrode 52.

In the present example embodiment of the mounting structure 90 for the multilayer ceramic capacitor (multilayer ceramic electronic component) 1, the dimension of each of the first external electrode 41 and the second external electrode 42 in the length direction L is preferably at least about 74% of the dimension of each of the first land electrode 51 and the second land electrode 52 in the length direction L, for example. This allows for increasing the contact area between the external electrodes and the paste solder, further preventing the multilayer ceramic capacitor 1 from floating and tilting during the mounting process of the multilayer ceramic capacitor 1, and further decreasing or preventing the reduction in stability of the mounting posture of the multilayer ceramic capacitor 1.

In the present example embodiment of the mounting structure 90 for the multilayer ceramic capacitor (multilayer ceramic electronic component) 1, the dimension of each of the first external electrode 41 and the second external electrode 42 in the width direction W may be between about 0.12 mm and about 0.21 mm inclusive, for example. Thus, the aforementioned effects can be achieved particularly in the small-sized multilayer ceramic capacitor 1.

While the example embodiments of the present invention have been described, the present invention is not limited to the example embodiments, and various modifications and variations can be made. For example, in the example embodiments, the multilayer ceramic capacitor using dielectric ceramics has been described as a multilayer ceramic electronic component. However, the aspects of the external electrodes of example embodiments of the present invention are not limited to these, and can be applied to various multilayer ceramic electronic components such as piezoelectric components using piezoelectric ceramics, thermistors using semiconductor ceramics, and inductors using magnetic ceramics. Piezoelectric ceramics may include PZT ceramics, etc., semiconductor ceramics may include spinel ceramics, etc., and magnetic ceramics may include ferrite, etc.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A mounting structure comprising a multilayer ceramic electronic component mounted on a circuit board, the multilayer ceramic electronic component including a multilayer body including a plurality of dielectric layers including ceramic material and a plurality of inner conductive layers stacked on each other, the multilayer body including two main surfaces on opposite sides in a thickness direction, two lateral surfaces on opposite sides in a width direction intersecting with the thickness direction, and two end surfaces on opposite sides in a length direction intersecting with both the thickness direction and the width direction; and
first and second external electrodes spaced apart in the length direction, provided on only the two main surfaces of the multilayer body or only one of the two main surfaces of the multilayer body; wherein
the circuit board includes a first land electrode and a second land electrode that are spaced apart in the length direction, and are respectively connected to the first external electrode and the second external electrode of the multilayer ceramic electronic component;
an inner edge of the first external electrode on a second external electrode side in the length direction is located closer to the second external electrode side and a second land electrode side, than an inner edge of the first land electrode on the second land electrode side in the length direction; and
an inner edge of the second external electrode on a first external electrode side in the length direction is located closer to the first external electrode side and a first land electrode side, than an inner edge of the second land electrode on the first land electrode side in the length direction.

2. The mounting structure for the multilayer ceramic electronic component according to claim 1, wherein
an outer edge of the first external electrode on a side opposite to the inner edge of the first external electrode in the length direction is located closer to the second external electrode side and the second land electrode side, than an outer edge of the first land electrode on a side opposite to the inner edge of the first land electrode in the length direction; and
an outer edge of the second external electrode on a side opposite to the inner edge of the second external electrode in the length direction is located closer to the first external electrode side and the first land electrode side, than an outer edge of the second land electrode on a side opposite to the inner edge of the second land electrode in the length direction.

3. The mounting structure for the multilayer ceramic electronic component according to claim 1, wherein a distance between the inner edge of the first external electrode and the inner edge of the second external electrode is shorter than a distance between the inner edge of the first land electrode and the inner edge of the second land electrode.

4. The mounting structure for the multilayer ceramic electronic component according to claim 1, wherein a dimension of each of the first and second external electrodes in the length direction is about 74% or more of a dimension of each of the first and second land electrodes in the length direction.

5. The mounting structure for the multilayer ceramic electronic component according to claim 1, wherein a dimension of each of the first and second external electrodes in the width direction is between about 0.12 mm and about 0.21 mm inclusive.

6. The mounting structure for the multilayer ceramic electronic component according to claim 1, wherein the multilayer ceramic electronic component is a multilayer ceramic capacitor.

7. The mounting structure for the multilayer ceramic electronic component according to claim 1, wherein the multilayer ceramic electronic component is a piezoelectric component.

8. The mounting structure for the multilayer ceramic electronic component according to claim 1, wherein the multilayer ceramic electronic component is a thermistor.

9. The mounting structure for the multilayer ceramic electronic component according to claim 1, wherein the multilayer ceramic electronic component is an inductor.

10. The mounting structure for the multilayer ceramic electronic component according to claim 1, wherein the multilayer ceramic electronic component includes piezoelectric ceramics, semiconductor ceramics, or magnetic ceramics.

11. The mounting structure for the multilayer ceramic electronic component according to claim 1, wherein each of the first and second external electrodes includes only a plated layer.

12. The mounting structure for the multilayer ceramic electronic component according to claim 1, wherein each of the first and second external electrodes includes a base electrode layer and a plated layer.

13. The mounting structure for the multilayer ceramic electronic component according to claim 12, wherein the base electrode layer is a fired layer including metal and glass.

14. The mounting structure for the multilayer ceramic electronic component according to claim 12, wherein the base electrode layer is a resin layer including electrically conductive particles and a thermosetting resin.

15. The mounting structure for the multilayer ceramic electronic component according to claim 12, wherein a thickness of the base electrode layer and a thickness of the plated layer is about 1 μm and about 10 μm inclusive.

16. The mounting structure for the multilayer ceramic electronic component according to claim 12, wherein the base electrode layer includes a thin film layer of metal particles deposited to a thickness of about 1 μm or less.

17. The mounting structure for the multilayer ceramic electronic component according to claim 12, wherein the plated layer covers at least a portion of the base electrode layer.

18. The mounting structure for the multilayer ceramic electronic component according to claim 12, wherein the plated layer includes Cu, Ni, Ag, Pd, Au, or an alloy or an Ag—Pd alloy.

19. The mounting structure for the multilayer ceramic electronic component according to claim 12, wherein the plated layer includes a plurality of layers.

20. The mounting structure for the multilayer ceramic electronic component according to claim 12, wherein the plated layer includes a Ni plated layer and a Sn plated layer.
